(19) United States
(12) Patent Application Publication
(10) Pub. No.: US 2016/0308167 A1
(43) Pub. Date: Oct. 20, 2016

(54) ORGANIC LIGHT-EMITTING ELEMENT

(71) Applicant: CORNING PRECISION MATERIALS CO., LTD., Chungcheongnam-do (KR)

(72) Inventors: Jeong Woo Park, Chungcheongnam-do (KR); Eui Soo Kim, Chungcheongnam-do (KR); Hong Yoon, Chungcheongnam-do (KR)

(73) Assignee: Corning Precision Materials Co., Ltd., Chungcheongnam-do (KR)

(21) Appl. No.: 15/101,291

(22) PCT Filed: Dec. 2, 2014
(86) PCT No.: PCT/KR2014/011668

§ 371 Date: Jun. 2, 2016

(30) Foreign Application Priority Data
Dec. 2, 2013 (KR) 10-2013-0148367

(51) Int. Cl. H01L 51/52

(52) U.S. Cl. CPC H01L 51/5268; H01L 51/5225

(57) ABSTRACT

The present invention relates to an organic light-emitting element and, more specifically, to an organic light-emitting element having a bottom emitting structure. To this end, the present invention provides the organic light-emitting element, comprising: a substrate; a light extraction layer formed on the substrate and having an exposure part which exposes the substrate; a flat layer for covering the substrate and the light extraction layer and having a flat top surface; an anode electrode formed on the flat layer; an organic light-emitting layer formed on the anode electrode; and a cathode electrode formed on the organic light-emitting layer in the same form as the light extraction layer.

### TECHNICAL FIELD

The present disclosure relates to an organic light-emitting diode (OLED), and more particularly, relates to an OLED having a bottom emission structure.

### BACKGROUND ART

Light-emitting devices may be generally divided into organic light-emitting devices (OLEDs) in which a light-emitting layer is formed from an organic material and inorganic light-emitting devices in which a light-emitting layer is formed from an inorganic material. OLEDs are self-emitting light sources based on the radiative decay of excitons in an organic light-emitting layer, the excitons being generated by the recombination of electrons injected through an electron injection electrode (cathode) and holes injected through a hole injection electrode (anode). OLEDs have a range of merits, such as low-voltage driving, self-emission, a wide viewing angle, high resolution, natural color reproducibility, and rapid response times.

Recently, research has been actively undertaken in order to apply OLEDs to a variety of devices, such as portable information devices, cameras, watches, office equipment, vehicle information display devices, televisions (TVs), display devices, illumination systems, and the like.

In order to improve the luminous efficiency of OLEDs, it is necessary to improve the luminous efficiency of a material that constitutes a light-emitting layer or to improve light extraction efficiency in terms of a level at which light generated by the light-emitting layer is extracted.

Here, light extraction efficiency depends on the refractive indices of the layers of materials that constitute an OLED. In a typical OLED, when a beam of light generated by the light-emitting layer is emitted at an angle greater than a critical angle, the beam of light may be totally reflected at the interface between a higher-refractivity layer, such as a transparent electrode layer, and a lower-refractivity layer, such as a glass substrate. This consequently lowers light extraction efficiency, thereby lowering the overall luminous efficiency of the OLED, which is problematic.

More specifically, only about 20% of light generated by an OLED is emitted externally and about 80% of the light generated is lost due to a waveguide effect originating from the difference in refractive indices between a glass substrate and an organic light-emitting layer that includes an anode, a hole injection layer (HIL), a hole transporting layer (HTL), an emissive layer (EML), an electron transporting layer (ETL), and an electron injection layer (EIL), as well as by the total internal reflection originating from the difference in refractive indices between the glass substrate and the ambient air. Here, the refractive index of the internal organic light-emitting layer ranges from 1.7 to 1.8, whereas the refractive index of indium tin oxide (ITO), generally used for the anode, is about 1.9. Since the two layers have a significantly low thickness, ranging from 200 nm to 400 nm, and the refractive index of the glass used for the glass substrate is about 1.5, a planar waveguide is thereby formed inside the OLED. It is estimated that the ratio of the light lost in the internal waveguide mode due to the above-described reason is about 45%. In addition, since the refractive index of the glass substrate is about 1.5 and the refractive index of the ambient air is 1.0, when light exits the interior of the glass substrate, a beam of the light having an angle of incidence greater than a critical angle is totally reflected and trapped inside the glass substrate. The ratio of the trapped light is commonly about 35%, and only about 20% of generated light is emitted externally.

In order to overcome the above-described problems, research into a light extraction layer able to externally extract 80% of the light that would otherwise be lost in the internal waveguide mode have been actively undertaken. The light extraction layer is generally divided into an internal light extraction layer and an external light extraction layer. In the case of the external light extraction layer, light extraction efficiency thereof can be improved by disposing a film including micro-lenses having a variety of shapes on the outer surface of the substrate. The improvement of light extraction efficiency does not significantly depend on the shape of micro-lenses. In addition, since an internal light extraction layer directly extracts light that would otherwise be lost in the light waveguide mode, the ability thereof to improve light extraction efficiency is greater than that of the external light extraction layer. However, the internal light extraction layer may act as an obstacle against light incident to the glass substrate at an angle close to a vertical angle. That is, the internal light extraction layer may cause light loss while realizing better light extraction effect than the outer extraction layer.

As illustrated in FIG. 1, an OLED having a bottom emission structure of the related art includes a substrate 10, an inner light extraction layer 20, a planarization layer 30, an anode 40, an organic light-emitting layer 50, and a cathode 60. The cathode 60 has high reflectance since the cathode 60 is formed as a metal thin film having a smaller work function in order to facilitate electron injection.

In the OLED having a bottom emission structure of the related art, the substrate 10 allows light to pass through, while the cathode 60 does not allow light to pass through. Thus, when power is off, the OLED maintains an opaque state, which is problematic.

### RELATED ART DOCUMENT

Patent Document 1: Korean Patent Publication Application No. 10-2012-0044675 (May 8, 2012)

### DISCLOSURE

### Technical Problem

Various aspects of the present disclosure provide an organic light-emitting diode (OLED) that can have a transparent state when no power is applied thereto.

### Technical Solution

According to an aspect, an OLED may include: a substrate; a light extraction layer disposed on the substrate, the light extraction layer having an exposing portion through which the substrate is exposed externally; a planarization layer covering the substrate and the light extraction layer, the planarization layer having a flat top surface; an anode disposed on the planarization layer; an organic light-emitting layer disposed on the anode; and a cathode disposed on the organic light-emitting layer, the shape and the position of the cathode being identical to and corresponding to the shape and the position of the light extraction layer, the cathode having an exposing portion, the shape of which is identical to the shape of the exposing portion of the light extraction layer.

The light extraction layer may have at least one opening, preferably, a plurality of openings arranged in a predetermined pattern. More preferably, the pattern is one selected from the group consisting of a stripe pattern, a grid pattern, a pattern of hexagonal portions, and a pattern of circular portions when the light extraction layer is viewed from vertically above.

The light extraction layer may include a plurality of light extraction sub-layers, preferably, a plurality of light extraction sub-layers arranged in a predetermined pattern. The distances between the plurality of light extraction sub-layers may range from 1 μm to 1 cm. The widths of the light extraction sub-layers may range from 1 μm to 1 mm.

The thickness of the light extraction layer may range from 100 nm to 10 μm.

The thickness of the planarization layer may range from 100 nm to 20 μm.

The thickness of the anode may range from 50 nm to 200 nm.

The thickness of the organic light-emitting layer may range from 50 nm to 1 μm.

The cathode may be formed as a metal thin film.

The thickness of the cathode may range from 10 nm to 500 nm.

### Advantageous Effects

As set forth above, the OLED can emit light with high efficiency when power is applied thereto while remaining transparent when no power is applied thereto.

### DESCRIPTION OF DRAWINGS

FIG. 1 is a cross-sectional view schematically illustrating an OLED having a bottom emission structure of the related art;

FIG. 2 is a cross-sectional view schematically illustrating an OLED according to an exemplary embodiment;

FIG. 3A, FIG. 3B, FIG. 3C, and FIG. 4D are top plan views illustrating light extraction layers according to exemplary embodiments;

FIG. 4 is a conceptual view illustrating routes along which external light passes through the OLED according to the exemplary embodiment when no power is applied; and

FIG. 5 is a conceptual view illustrating routes along which emission light travels through the OLED according to the exemplary embodiment when power is applied.

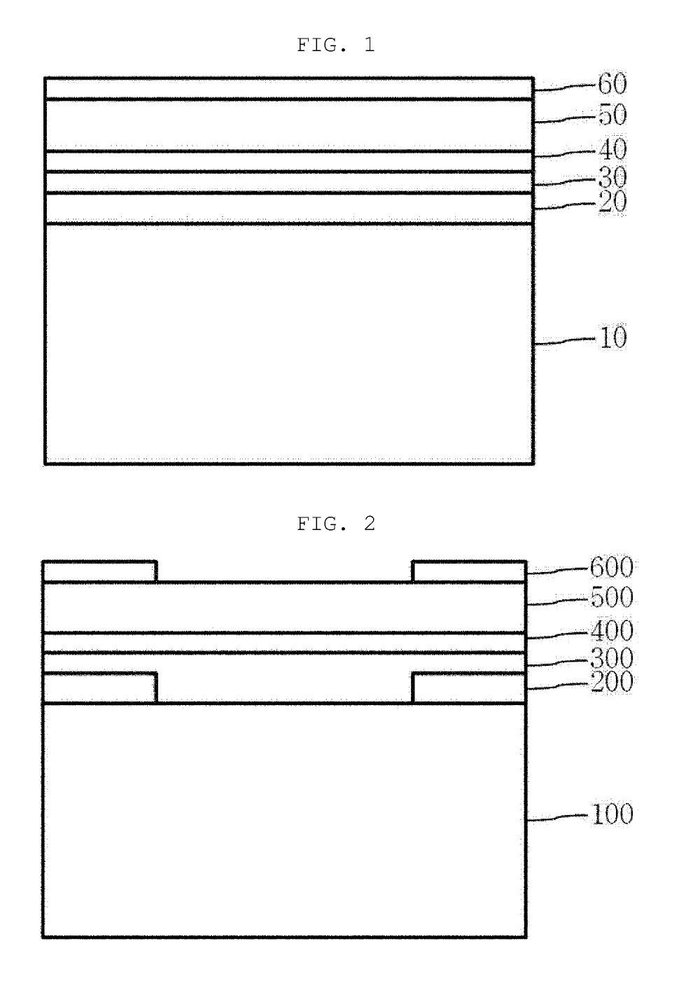

### MODE FOR INVENTION

Hereinafter, reference will be made to an organic light-emitting diode (OLED) according to the present disclosure in detail, embodiments of which are illustrated in the accompanying drawings.

In the following description, detailed descriptions of known functions and components incorporated herein will be omitted in the case that the subject matter of the present disclosure is rendered unclear by the inclusion thereof.

FIG. 2 is a cross-sectional view schematically illustrating an OLED according to an exemplary embodiment.

As illustrated in FIG. 2, the OLED according to the present embodiment includes a substrate 100, a light extraction layer 200, a planarization layer 300, an anode 400, an organic light-emitting layer 500, and a cathode 600.

The substrate 100 supports the light extraction layer 200. In addition, the substrate 100 is disposed on the front portion of the OLED through which light generated by the OLED is emitted externally, allowing light generated by the OLED to pass through, while serving as an encapsulation substrate protecting the OLED from the external environment.

The substrate 100 may be formed from any transparent material that has superior light transmittance and mechanical properties. For example, the substrate 100 may be formed from a polymeric material, for example, a thermally or ultraviolet (UV) curable organic film. Alternatively, the substrate 100 may be a chemically strengthened glass substrate formed from, for example, soda-lime glass (SiO₂-CaO-Na₂O) or aluminosilicate glass (SiO₂-Al₂O₃-Na₂O). When the OLED according to the present embodiment is applied to a lighting system, the substrate 100 may be formed from soda-lime glass. The substrate 100 may also be a substrate formed from a metal oxide or a metal nitride. According to the present embodiment, the substrate 100 may be a thin glass substrate having a thickness of 1.5 mm or less. The thin glass substrate may be fabricated using a fusion process or a floating process.

The light extraction layer 200 is formed on the substrate 100, and has an exposing portion through which the substrate 100 is exposed externally.

The light extraction layer reduces total reflection and wave-guiding of light generated by the organic light-emitting layer at the interface between the anode and the substrate and at the interface between the anode and the organic light-emitting layer, thereby improving the luminous efficiency of the OLED.

The light extraction layer may have any structure that can improve the internal light extraction efficiency of the OLED by inducing light scattering. For example, the light extraction layer may include a material area, the refractive index of which is 1.5 or higher, and more particularly, the refractive index of which ranges from 1.5 to 3.0. When a material, the refractive index of which is 1.5 or higher, is included in the light extraction layer, the effect of light scattering may be obtained based on the difference in the refractive index between the material and the other areas.

The light extraction layer may be formed from one selected from among inorganic materials, organic materials, and mixtures thereof. The available inorganic materials may include SnO₂, TiO₂, CdO, TiO₂-SiO₂, ZrO₂, ZnO, ZnS, Cu₂O, Ta₂O₃, HfO₂, and In₂O₃. The organic materials may include polyvinyl phenol resin, epoxy resin, polyimide resin, polystyrene resin, polycarbonate resin, polyethylene resin, polymethyl methacrylate (PMMA) resin, polypropylene resin, and siloxane-based resin.

The exposing portion may be formed by coating the substrate 100 with a material that will form the light extraction layer and then selectively etching the coated light extraction layer.

It is preferable that the thickness of the light extraction layer 200 may range from 100 nm to 10 μm.

In addition, the light extraction layer 200 may include therein scattering particles to scatter light, thereby further improving the light extraction efficiency.

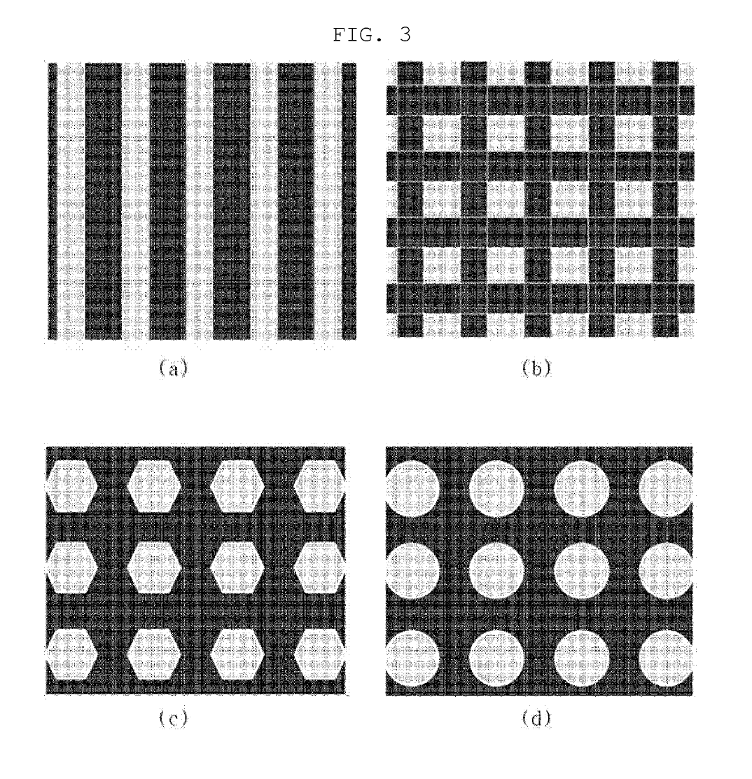

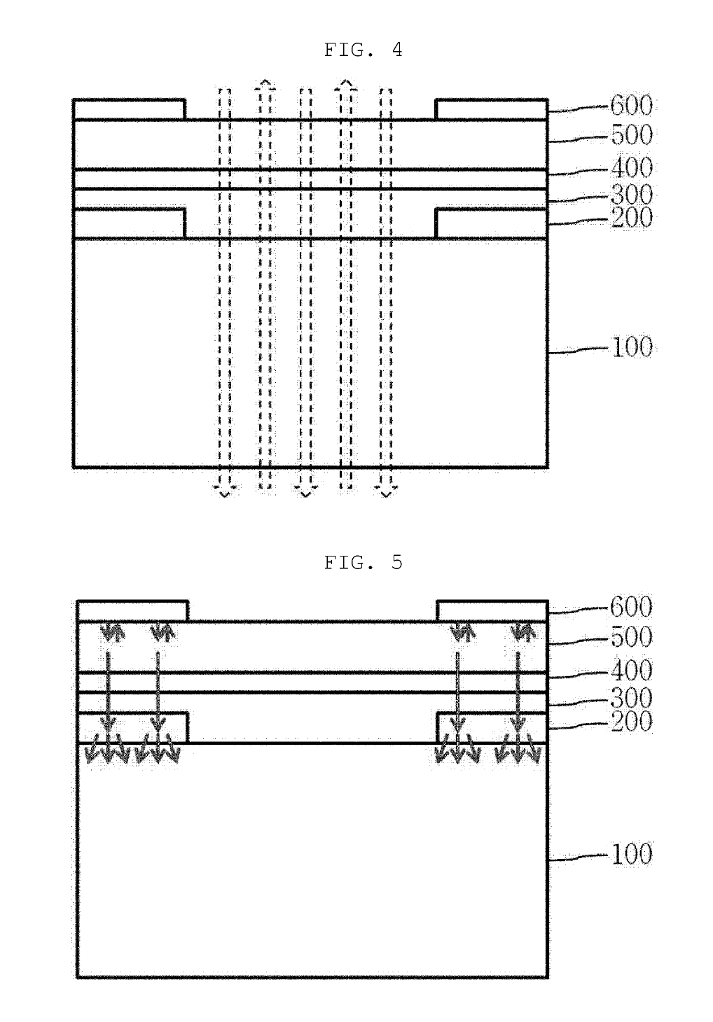

The light extraction layer 200 may have one or more openings through which the substrate is exposed externally. It is preferable that the light extraction layer 200 may have a plurality of openings having a predetermined pattern. FIG. 3A, FIG. 3B, FIG. 3C, and FIG. 4D are top plan views illustrating light extraction layers according to exemplary embodiments. FIG. 3A illustrates openings formed in a stripe pattern, FIG. 3B illustrates openings formed in a grid pattern, FIG. 3C illustrates openings having hexagonal shapes, and FIG. 3D illustrates openings having circular shapes. However, the patterns and shapes of the openings are not limited thereto.

In an embodiment, the light extraction layer 200 may include a plurality of light extraction sub-layers. The plurality of light extraction sub-layers may be spaced apart from each other. Here, the plurality of light extraction sub-layers may have a predetermined pattern. It is preferable that the distances between the light extraction sub-layers range from 1 μm to 1 cm, and that the widths of the light extraction sub-layers range from 1 μm to 1 mm.

The planarization layer 300 has a flat top surface covering the substrate 100 and the light extraction layer 200.

The planarization layer 300 planarizes stepped portions formed of the exposing portions of the light extraction layer 200, such that the anode 400 can be formed into a flat structure. This structure can consequently prevent current from leaking from the anode 400, thereby preventing the electrical characteristics of the OLED from degrading.

It is preferable that the planarization layer 300 is formed from a material, the refractive index of which is the same as or similar to the refractive index of the anode 400, in order to improve light extraction efficiency. For example, the planarization layer 300 may be formed from one selected from among high refractive frit, SiO₂, TiO₂, and ZnOx.

It is preferable that the thickness of the planarization layer 300 ranges from 100 nm to 20 μm.

The anode 400 is formed on the planarization layer 300 to act as a positive (+) electrode of the OLED.

The anode 400 is formed from a transparent conductive material, more particularly, one selected from among metals and metal oxides, such as Au, In, Sn, and ITO, having a greater work function to facilitate hole injection.

It is preferable that the thickness of the anode 400 ranges from 50 nm to 200 nm.

The organic light-emitting layer 500 is formed on the anode 400 to generate light in response to a flow of current applied between the anode 400 and the cathode 600.

The organic light-emitting layer 500 as described above includes a hole injection layer (HIL), a hole transporting layer (HTL), an emissive layer (EML), an electron transporting layer (ETL), and an electron injection layer (EIL).

Due to this structure, when a forward voltage is applied between the anode 400 and the cathode 600, electrons from the cathode 600 migrate to the EML through the EIL and the ETL, while holes from the anode 400 migrate to the EML through HIL and the HTL. The electrons and the holes that have migrated into the EML recombine with each other, thereby generating excitons. When the excitons transit from an excited state to a ground state, light is emitted. The brightness of emission light is proportional to the amount of current flowing between the anode 400 and the cathode 600.

It is preferable that the thickness of the organic light-emitting layer 500 ranges from 50 nm to 1 μm.

The cathode 600 is formed on the organic light-emitting layer 500, in the same shape as the light extraction layer 200, to act as a negative (−) electrode of the OLED.

Specifically, the shape and size of the cathode 600 the same as the shape and size of the light extraction layer 200, and the cathode 600 is formed on the organic light-emitting layer 500 to correspond to the light extraction layer 200.

Thus, the cathode 600 has exposing portions through which the organic light-emitting layer 500 is exposed externally. In addition, the cathode 600 may have one or more openings, preferably, a plurality of openings arranged in a predetermined pattern, through which the organic light-emitting layer 500 is exposed externally. Furthermore, the cathode 600 may include a plurality of sub-cathodes. In this case, it is preferable that the distances between the sub-cathodes range from 1 μm to 1 cm, and that the widths of the sub-cathodes range from 1 μm to 1 mm. When the distances between the sub-cathodes are less than 1 μm, light may be distorted due to the interference or diffraction of light. When the distances between the sub-cathodes exceed 1 cm, the OLED cannot obtain a sufficient intensity of light.

The cathode 600 may be formed as a metal thin film having a smaller work function in order to facilitate electron injection. It is preferable that the cathode 600 is formed from Al, Al:Li, or Mg:Ag.

In addition, it is preferable that the thickness of the cathode 600 ranges from 10 nm to 500 nm.

Since the OLED according to the present embodiment is configured as described above, the OLED can emit light with high efficiency when power is applied thereto while remaining transparent when no power is applied thereto.

Describing in greater detail with reference FIG. 4, when no power is applied to the OLED, external light passes through the OLED in opposite directions, more particularly, through the exposing portion formed in the cathode 600, such that the OLED can have a transparent state.

In addition, since the light extraction layer 200 has the same shape as the cathode, it is possible to minimize the scattering of light by the light extraction layer 200 during passing through the OLED. This can consequently reduce hazing caused by the light extraction layer 200, whereby the OLED can have high transmittance when no power is applied thereto.

In contrast, as illustrated in FIG. 5, when power is applied to the OLED, light that has entered the light extraction layer 200 after being generated by the organic light-emitting layer 500 is emitted in the direction of the substrate with high efficiency through light extraction by the light extraction layer 200 and diffusion due to hazing in the light extraction layer 200.

The foregoing descriptions of specific exemplary embodiments of the present disclosure have been presented with respect to the drawings. They are not intended to be exhaustive or to limit the present disclosure to the precise forms disclosed herein, and many modifications and variations are obviously possible for a person having ordinary skill in the art in light of the above teachings.

It is intended therefore that the scope of the present disclosure not be limited to the foregoing embodiments, but be defined by the Claims appended hereto and their equivalents.

### DESCRIPTION OF THE REFERENCE NUMERALS IN THE DRAWINGS

10, 100: substrate; 20, 200: light extraction layer

30, 300: planarization layer; 40, 400: anode

50, 500: organic light-emitting layer; 60, 600: cathode

1. An organic light-emitting diode comprising:
a substrate;
a light extraction layer disposed on the substrate, the light extraction layer comprising an exposing portion through which the substrate is exposed externally;
a planarization layer covering the substrate and the light extraction layer, the planarization layer having a flat top surface;
an anode disposed on the planarization layer;
an organic light-emitting layer disposed on the anode; and
a cathode disposed on the organic light-emitting layer, a shape of the cathode being identical to a shape of the light extraction layer.

2. The organic light-emitting diode of claim 1, wherein the light extraction layer has at least one opening.

3. The organic light-emitting diode of claim 2, wherein the light extraction layer has a plurality of openings arranged in a predetermined pattern.

4. The organic light-emitting diode of claim 3, wherein the pattern is one selected from the group consisting of a stripe pattern, a grid pattern, a pattern of hexagonal portions, and a pattern of circular portions when the light extraction layer is viewed from vertically above.

5. The organic light-emitting diode of claim 1, wherein the light extraction layer comprises a plurality of light extraction sub-layers.

6. The organic light-emitting diode of claim 5, wherein the plurality of light extraction sub-layers are arranged in a predetermined pattern.

7. The organic light-emitting diode of claim 5, wherein distances between the plurality of light extraction sub-layers range from 1 μm to 1 cm.

8. The organic light-emitting diode of claim 1, wherein widths of the plurality of light extraction sub-layers range from 1 μm to 1 mm.

9. The organic light-emitting diode of claim 1, wherein a thickness of the light extraction layer ranges from 100 nm to 10 μm.

10. The organic light-emitting diode of claim 1, wherein a thickness of the planarization layer ranges from 100 nm to 20 μm.

11. The organic light-emitting diode of claim 1, wherein a thickness of the anode ranges from 50 nm to 200 nm.

12. The organic light-emitting diode of claim 1, wherein a thickness of the organic light-emitting layer ranges from 50 nm to 1 μm.

13. The organic light-emitting diode of claim 1, wherein the cathode comprises a metal thin film.

14. The organic light-emitting diode of claim 1, wherein a thickness of the cathode ranges from 10 nm to 500 nm.
